(19) United States
(12) Patent Application Publication
(10) Pub. No.: US 2025/0068059 A1
(43) Pub. Date: Feb. 27, 2025

(54) SUBSTRATE PROCESSING METHOD, SUBSTRATE PROCESSING APPARATUS, AND RECORDING MEDIUM

(71) Applicant: Tokyo Electron Limited, Tokyo (JP)

(72) Inventor: Hiroyuki Ide, Koshi City (JP)

(21) Appl. No.: 18/813,332

(22) Filed: Aug. 23, 2024

(30) Foreign Application Priority Data
Aug. 24, 2023 (JP) 2023-136558

(51) Int. Cl. G03F 1/82; G03F 7/00

(52) U.S. Cl. CPC G03F 1/82; G03F 7/70925

(57) ABSTRACT

A substrate processing method of patterning a resist film formed on a substrate by exposing and developing the resist film is provided. The substrate processing method includes performing, before forming the resist film containing a metal on the substrate, an auxiliary process of adjusting moisture adhesion to a formation surface of the substrate on which the resist film is to be formed.

### CROSS-REFERENCE TO RELATED APPLICATION

This application claims the benefit of Japanese Patent Application No. 2023-136558 filed on Aug. 24, 2023, the entire disclosures of which are incorporated herein by reference.

### TECHNICAL FIELD

The various aspects and embodiments described herein pertain generally to a substrate processing method, a substrate processing apparatus, and a recording medium.

### BACKGROUND

In the manufacture of a semiconductor device, photolithography is performed on a semiconductor wafer (hereinafter, simply referred to as a wafer). For a case of using, for example, a chemically amplified resist liquid in this photolithography, Patent Document 1 describes an apparatus configured to perform formation of a resist film on the wafer, development of the resist film after being exposed, and hydrophobization. This hydrophobization is performed by supplying a HMDS (hexamethyl disiloxane) gas to a surface of the wafer to suppress the resist film from being separated from the surface of the wafer.
Patent Document 1: Japanese Patent Laid-open Publication No. 2013-004804

### SUMMARY

In an exemplary embodiment, there is provided a substrate processing method of patterning a resist film formed on a substrate by exposing and developing the resist film. The substrate processing method includes performing, before forming the resist film containing a metal on the substrate, an auxiliary process of adjusting moisture adhesion to a formation surface of the substrate on which the resist film is to be formed.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view illustrating a substrate processing system according to an exemplary embodiment;

FIG. 2 is a longitudinal front view illustrating the substrate processing system;

FIG. 3 is a longitudinal side view illustrating an apparatus configured to perform hydrophobization in the substrate processing system;

FIG. 4 is a graph showing a temperature variation of a substrate in the hydrophobization;

FIG. 5 is a schematic diagram illustrating a chemical change in a resist;

FIG. 6 is a schematic diagram illustrating a chemical change in a metal where dehydration condensation occurs after exposure;

FIG. 7 is an explanatory diagram for describing timings for a processing and a transfer of a wafer in each module;

FIG. 8 is a graph showing a result of Evaluation Test 1; and

FIG. 9 is a graph showing a result of Evaluation Test 2.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

### <Substrate Processing System>

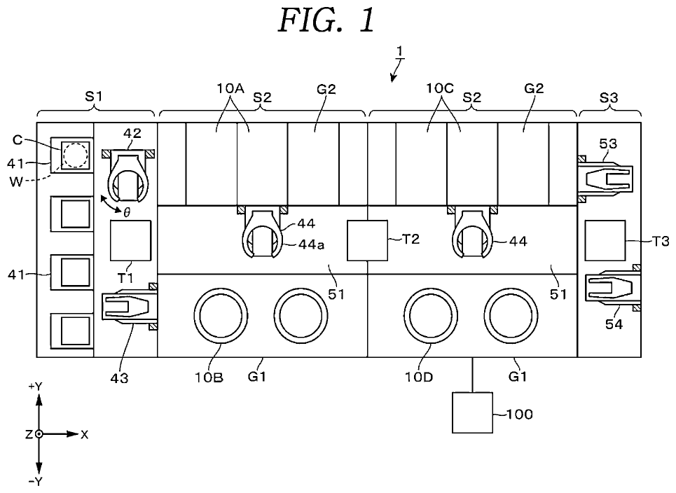

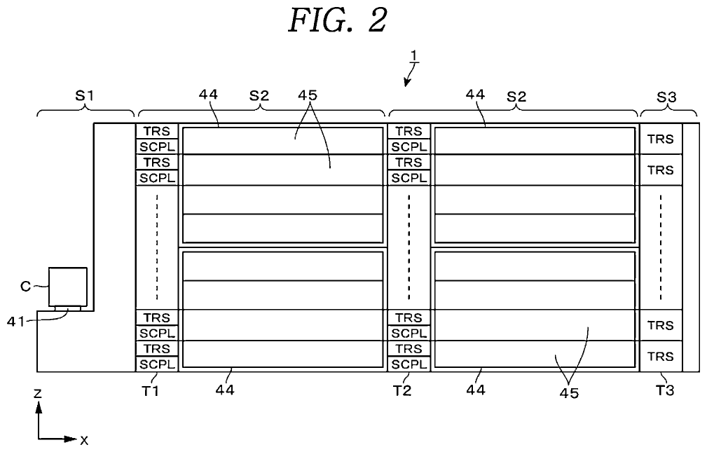

Hereinafter, a substrate processing system 1 including, as a module, a substrate processing apparatus according to an exemplary embodiment will be described with reference to a plan view of FIG. 1 and a longitudinal front view of FIG. 2. Further, in the present specification, parts having substantially same functions and configurations will be assigned same reference numerals, and redundant description thereof will be omitted. The substrate processing system 1 constitutes a system configured to perform photolithography on a wafer W, and, for example, is a system configured to form a resist film on the wafer W and develop it.

The substrate processing system 1 has a configuration in which a cassette station S1, one or more (for example, two) processing stations S2, and an interface station S3 are connected horizontally in this order. Hereafter, a direction along the row of these stations S1 to S3 is referred to as a left-and-right direction. In addition, this left-and-right direction is a direction along the X-axis direction to be described later, and may sometimes be referred to as the X-direction. When viewed from the top, a direction orthogonal to the X-axis direction will be referred to as the Y-axis direction, and a direction orthogonal to the X- and Y-axis directions will be referred to as the Z-axis direction. This Z-axis direction may sometimes be referred to as an up-and-down direction. Additionally, the substrate processing system 1 is provided in a clean room under an atmospheric pressure (normal pressure). Except for a processing in some modules to be described later, the wafer W is transferred and processed under the atmospheric pressure.

The cassette station S1 is configured to carry in and out a cassette C accommodating therein a plurality of wafers W. The processing station S2 is equipped with a plurality of various types of processing modules 10A to 10D each configured to perform a predetermined processing on the wafer W. The interface station S3 is connected to an exposure device (not shown) on its side opposite to the side to which the processing station S2 is connected, and is configured to transfer the wafer W between the exposure device and the processing station S2. Further, although the two processing stations S2 are disposed between the cassette station S1 and the interface station S3, one or more than two may be disposed.

The cassette station S1 is provided with a cassette placement table 41, transfer devices 42 and 43, and a tower T1. The tower T1 is equipped with a plurality of transition modules TRS arranged in a vertical direction, and towers T2 and T3 to be described later have the same configuration as the tower T1. Alternatively, the tower T1 may be disposed within the processing station S2.

The cassette placement table 41 is configured to place thereon the cassette C, which is a transfer container for the wafer W. Each of the transfer devices 42 and 43 is configured to transfer the wafer W between the cassette C on the cassette placement table 41 and the processing station S2. Specifically, each of the transfer devices 42 and 43 is equipped with a driving mechanism in such a direction as the X-axis direction, the Y-axis direction, the Z-axis direction, and a vertical direction (0 direction) when necessary, and may be equipped with driving mechanism in all of these directions. As for this driving mechanism, the same applies to transfer devices 44, 53, and 54 to be described later.

At least one of these transfer devices 42 and 43 is capable of transferring the wafer W to/from the cassette C, and at least the other is capable of transferring the wafer W to/from the processing station S2. Further, a transfer operation of the wafer W to/from the processing station S2 means, for example, an operation of transferring the wafer W to/from the tower T1 accessible by the transfer device 44 in the processing station S2 to be described later. Furthermore, the cassette station S1 may be equipped with, at a position accessible by either one of the transfer devices 42 and 43, an inspection device (not shown) configured to inspect the wafer W.

As shown in FIG. 2, the processing station S2 includes, for example, eight floors 45 stacked in the vertical direction, first and second blocks G1 and G2 disposed on each floor 45, and the tower T2 extending in the vertical direction across these floors 45. The tower T2 is located at a boundary position between the two processing stations S2, S2. In the towers T1 and T2, a temperature regulating module SCPL and a transition module TRS are provided at a height corresponding to each floors 45, for example. Each transition module TRS is configured to temporarily place therein the wafer W to be accessed by a corresponding transfer device for the delivery of the wafer W, and each temperature regulating module SCPL has an accommodation section for accommodating the wafer W therein, and is configured to regulate the temperature of the wafer W accommodated therein.

The first block G1 is disposed on the front side (negative Y-axis side in FIG. 1) of processing station S2, and the second block G2 is disposed on the rear side (positive Y-axis side in FIG. 1) of the processing station S2. The first block G1 includes a plurality of liquid processing modules, for example, a plurality of coating modules (resist film forming modules) 10B configured to coat a resist liquid to form a resist film, a plurality of developing modules 10D, and so forth, and may additionally include a module configured to form an anti-reflection film. The plurality of processing modules, such as the coating modules 10B and the developing modules 10D, are arranged in a horizontal direction in each floor 45, and the number, the layout, and the type of these processing modules may be selected as required.

These coating modules 10B and developing modules 10D perform various types of processings by supplying predetermined processing liquids onto the wafer W, for example. In this way, in the coating module 10B, formation of the resist film to be used as a mask when forming a pattern of a film on the lower layer side, and formation of an anti-reflection film for efficiently performing light radiation, such as an exposure process, are performed. In the developing module 10D, the mask is formed by removing a portion of the resist film that has not been irradiated with light in the exposure process.

The second block G2 includes heat treatment modules 10C configured to perform heat treatments such as heating and cooling of the wafer W, hydrophobizing modules 10A as a substrate processing apparatus, and non-illustrated peripheral exposure modules configured to expose an outer peripheral portion of the wafer W arranged in a vertical direction and a horizontal direction, respectively. The number and the layout of these heat treatment modules 10C, hydrophobizing modules 10A, and peripheral exposure modules may also be selected as required.

As shown in FIG. 1, when viewed from the top, a transfer region 51 is provided in an area sandwiched between the first block G1 and the second block G2. The transfer region 51 is a space extending in the X-axis direction at the center of the Y-axis direction of each floor 45, and also extending from the uppermost floor 45 to the lowermost floor 45. In the transfer region 51, a plurality of transfer devices 44, for example, may be arranged in the Z-axis or X-axis direction.

The transfer device 44 disposed in the processing station S2 near the cassette station S1 moves in the transfer region 51 to transfer the wafer W to the first block G1, the second block G2, and the respective modules in the towers T1 and T2 around. The transfer device 44 provided in the processing station S2 near the interface station S3 moves in the transfer region 51 to transfer the wafer W to the first block G1, the second block G2, and the respective modules in the towers T2 and T3 around.

The plurality of transfer devices 44 are arranged vertically, as shown in FIG. 2, for example. By way of example, the transfer device 44 on the upper side is configured to transfer the wafer W to each of the modules located at the heights of the upper four floors 45, and the transfer device 44 on the lower side is configured to transfer the wafer W to each of the modules located at the heights of the four lower floors 45. The transfer of the wafer W to the respective modules disposed to surround the transfer region 51 can be appropriately carried out by the plurality of transfer devices 44. Further, the number of the transfer devices 44 and the number of the floors 45 accessible by one transfer device 44 can be selected as required. By way of example, there may be adopted a configuration in which the transfer device 44 is provided for each floor 45.

Additionally, a shuttle transfer device (not shown) may be provided in the transfer region 51, or the first block G1 and the second block G2. The shuttle transfer device is configured to linearly transfer the wafer W between a space adjacent to one side of the processing station S2 and another space adjacent to the other side of the processing station S2.

The interface station S3 is provided with the tower T3, and the transfer devices 53 and 54 provided near the tower T3 and configured to be movable up and down. The interface station S3 transfers the wafer W between the tower T3 and the exposure device by using the transfer devices 53 and 54. At least one of the transfer devices 53 and 54 is capable of transferring the wafer W between the exposure device and the transfer module TRS in the tower T3 while supporting the wafer W thereon.

In addition, the interface station S3 may be provided with, at a position accessible by either one of the transfer devices 53 and 54, a cleaning device configured to clean a surface of the wafer W and the aforementioned peripheral exposure device. Further, although the aforementioned inspection device may be provided in the cassette station S1, it may be provided in the processing station S2 or the interface station S3. In this case, the inspection device may be provided at a position accessible by the transfer arm (44, 53, or 54 in FIG. 1 and FIG. 2) of any one of the transfer devices provided therein.

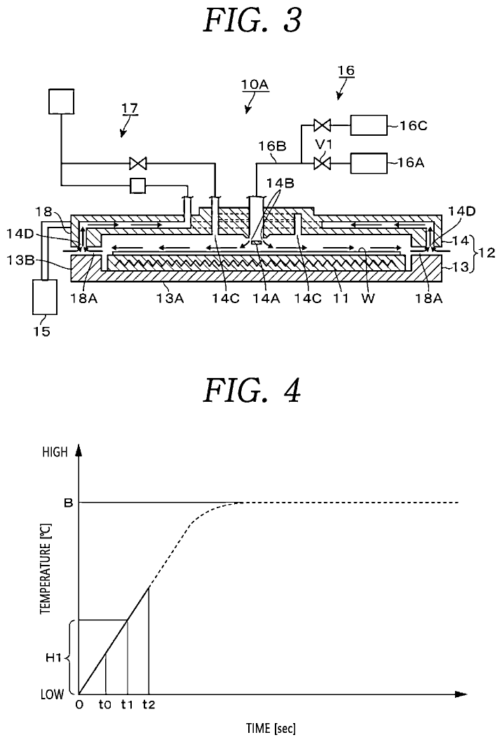

As a representative of the above-described processing modules 10A to 10D, the structure of the hydrophobizing module 10A will first be described in detail with reference to FIG. 3. The hydrophobizing module 10A is equipped with a hot plate 11 having a heater embedded therein, and a processing vessel 12 surrounding the hot plate 11, and is configured to supply a hydrophobizing gas to the wafer W disposed on the hot plate 11 to perform hydrophobization of a top surface of the wafer W. This top surface is a formation surface on which a resist film is to be formed later, and is therefore in contact with the resist film. Further, the top surface is a front surface formed by an underlayer film that is etched by using the resist film as a mask after the formation of the resist pattern.

The processing vessel 12 includes a vessel body 13 and a top plate 14. The vessel body 13 includes a lower covering member 13A that covers a lower portion of the hot plate 11, and a lower sidewall 13B protruding upwards from a periphery of the lower covering member 13A and surrounding a side periphery of the hot plate 11. The top plate 14 is configured to be raised and lowered with respect to the vessel body 13 by an elevating mechanism 15, and is moved between a lower position (the position shown in the drawing) where a processing space is formed and the wafer W is processed and an upper position where the processing space is not formed and the wafer W is transferred to/from the hot plate 11. Although not shown, the hot plate 11 is equipped with three pins configured to be protruded from and recessed into a top surface of the hot plate 11 with the top plate 14 located above, thus allowing the wafer W to be transferred between the hot plate 11 and the transfer device 44 moved to above the hot plate 11.

A lower central portion of the top plate 14 projects downwards to form a circular protrusion 14A, and a plurality of discharge openings 14B are opened in a side periphery of the protrusion 14A at a certain distance therebetween in a circumferential direction of the protrusion 14A. A hydrophobizing gas is supplied to the discharge openings 14B from a gas supply mechanism 16 provided outside the processing vessel 12, and the hydrophobizing gas discharged from the discharge opening 14B flows, on the surface of the wafer W heated by the hot plate 11, from a central portion of the wafer W toward a peripheral portion thereof. A plurality of exhaust ports 14C and 14D, which are connected to an exhaust mechanism 17 such as, but not limited to, a vacuum pump, are formed in a bottom surface of the top plate 14 on a peripheral side than the protrusion 14A. With this configuration, an atmosphere inside the processing vessel 12 can be properly exhausted through the exhaust ports 14C and 14D, and an exterior air can be sucked in, as will be described later.

This hydrophobizing gas is composed of, by way of non-limiting example, a silane coupling agent, and, as a more specific example, is a HMDS gas. A source 16A of the gas supply mechanism 16 includes a storage for a HMDS liquid and a vaporizer configured to vaporize the HMDS liquid into the HMDS gas. The supply and stop of the supply of the HMDS gas from the discharge openings 14B are switched as a valve V1 provided in a flow path 16B connecting the gas supply mechanism 16 and the top plate 14 are opened and closed. The gas supply mechanism 16 is connected to the flow path 16B, and is equipped with a purge gas source 16C for supplying, for example, a nitrogen gas.

A peripheral portion of the top plate 14 protrudes downwards, forming an upper sidewall 18 whose bottom surface configured to come into contact with the lower sidewall 13B. A plurality of suction ports 18A are opened at the bottom surface of this upper sidewall 18 at a certain distance therebetween in a circumferential direction of the upper sidewall 18. Each suction port 18A extends along a diametrical direction of the top plate 14. With the top plate 14 located at the lower position, the suction port 18A of the top plate 14 is close to the lower sidewall 13B, and the air outside the processing vessel 12 is sucked in through this suction port 18A.

When supplying the HMDS gas, by performing the exhaust of the atmosphere inside the processing vessel 12 through the exhaust opening 14D instead of performing it through the exhaust port 14C, the HMDS gas is made to flow to the peripheral portion of the wafer W and is introduced into the suction port 18A together with the exterior air to be removed through the exhaust port 14D. Concurrently with an end of the supply of the HMDS gas, which is an end of the hydrophobization, a supply of a purge gas from the purge gas source 16C, for example, is started. Even during the supply of the purge gas, the exhaust through the exhaust ports 14C and 14D is performed.

The other processing modules 10B to 10D will be briefly explained, focusing on differences from the hydrophobizing module 10A described above. Each of the coating module 10B and the developing module 10D includes a holder configured to attract and hold a center of a rear surface of the wafer W, a rotating mechanism configured to rotate the holder, and a nozzle configured to supply a processing liquid to a front surface of the wafer W, and is configured to supply the processing liquid to the entire front surface of the wafer W. The coating module 10B is configured to supply a resist liquid as the processing liquid to the wafer W, and forms a resist film by spin coating. The developing module 10D is configured to supply coat a developing liquid as the processing liquid, and develops the resist film.

The resist liquid applied by the coating module 10B is a metal-containing resist, and, more specifically, is a metal oxide resist (MOR). Further, the metal-containing resist contains a metal as a component of the resist, and does not mean a resist containing the metal only as an impurity. The metal as the component of the resist is, by way of example, tin (Sn). Hereinafter, unless otherwise specified, it is assumed that the resist is a MOR. This MOR is, for example, a negative resist, and the formed resist film is exposed to, for example, EUV (Extreme ultraviolet). The hydrophobization by the above-described hydrophobizing module 10A is an effective auxiliary process in forming a pattern by exposing and developing the resist film, and the reason why this auxiliary process is performed will be described later.

The heat treatment modules 10C are stacked vertically in the second block G2, and are also arranged side by side in the left-and-right direction. Each heat treatment module 10C is equipped with a hot plate configured to heat the wafer W placed thereon. Using these heat treatment modules 10C, a heat treatment performed on the wafer W after forming the resist film and before performing the exposure will sometimes be referred to as PAB (Post Apply Bake), a heat treatment performed after the exposure but before the development will sometimes be referred to as PEB (Post Exposure Bake), and a heat treatment performed after the development will sometimes be referred to as HB (Hard Bake).

The above-described substrate processing system 1 is provided with a control device 100. The control device 100 is, for example, a computer, and has a program storage (not shown). The program storage stores a program for controlling the processes on the wafer W in the substrate processing system 1. Also, the program storage stores a program for executing the processes on the wafer W in the substrate processing system 1 by controlling the operations of a driving system, such as the above-described various processing apparatuses and transfer devices. The above-described programs are recorded on a computer-readable recording medium, and may be installed into the control device 100 from the recording medium.

### <Operation of Substrate Processing System>

A wafer processing operation performed in the substrate processing system 1 configured as described above will be explained.

First, the cassette C accommodating the plurality of wafers W therein is carried into the cassette station S1 of the substrate processing system 1 to be placed on the cassette placement table 41. Then, each of the wafers W is sequentially taken out from the cassette C by any either one of the transfer devices 42 and 43, and is transferred to any one of the transition modules TRS of the tower T1. The wafer W transferred to the corresponding transition module TRS is supported by the transfer device 44 and is transferred to the hydrophobizing module 10A of the second block G2 to be subjected to the hydrophobization. Hereinafter, the hydrophobization in the hydrophobizing module 10A will be described in detail.

Before the wafer W is transferred, the hot plate 11 of the hydrophobizing module 10A is heated by the heater to a set temperature B of, for example, 80° C. to 120° C. The wafer W is carried in the space between the vessel body 13 and the top plate 14 at the upper position, and the wafer W is placed on the hot plate 11. Subsequently, the top plate 14 is lowered to the lower position to form the processing space. Next, the valve V1 is opened to a predetermined opening degree, and the HMDS gas is supplied from the gas supply mechanism 16 into the processing space at a predetermined flow rate. The HMDS gas flows so as to diffuse over the wafer W from the center side of the wafer W toward the outer periphery thereof, so that the surface of the wafer W (the surface on which the above-described resist film is formed) is made hydrophobic.

A supply time of the HMDS gas, which is a hydrophobization time, is desirably 10 seconds or less, as shown in evaluation tests to be described later. By such a relatively short hydrophobization process, the degree of hydrophobicity of the surface of the wafer W is adjusted to a required level. The adjustment of the hydrophobicity (that is, adjustment of moisture adhesion to the surface on which the resist film is formed) will be described in detail. The hydrophobization performed as described above is a process of replacing a hydroxyl group, which is a hydrophilic group present on the surface of the wafer W, with a hydrophobic group of (CH₃)₃—SiO, and the adjustment of the moisture adhesion is to stop the supply of the HMDS gas to the wafer W in the state that an unreacted hydroxyl group remains, to thereby stop the reaction. Thus, this adjustment also means, if the supply of the HMDS gas is continued, stopping the supply of the HMDS gas when the additional replacement with the hydrophobic group is in progress to thereby stop the above-described replacement reaction. Therefore, in terms of a contact angle of water with the surface of the wafer W, the aforementioned hydrophobization time is set so as to obtain a contact angle smaller than a contact angle that is obtained if the HMDS gas is supplied for a time longer than this hydrophobization time. As a specific example, the hydrophobization time in this hydrophobizing module 10A is set such that the contact angle with pure water is equal to or greater than 30 degrees and less than 65 degrees.

FIG. 4 shows a relationship between the temperature of the wafer W placed on the hot plate 11 and time when performing the hydrophobization as described above. A solid line of the graph represents an actual temperature variation of the wafer W, and a dotted line represents a virtual temperature variation. A horizontal axis of the graph represents an elapsed time from 0 second at which the wafer W is placed on the hot plate 11, and a vertical axis represents the temperature of the wafer W. As the wafer W is placed on the hot plate 11, the temperature of the wafer W increases. For example, if the time during which the wafer W is placed on the hot plate 11 is relatively long, the temperature of the wafer W reaches a set temperature B of the hot plate 11, as shown by the dotted line of the graph. That is, the temperature rise saturates at the set temperature B. A time to is a set time at which the valve V1 configured to perform the supply and the stop of the supply of the HMDS gas into the processing vessel 12 is opened, and a time t1 is a set time at which the valve V1 is closed. Therefore, the time length from the time to to the time t1 is the hydrophobization time.

As described, for the purpose of adjusting the moisture adhesion to the surface of the wafer W, the hydrophobization time is set to be relatively short. Therefore, the time t1 is a time before the temperature of the wafer W reaches the set temperature B of the hot plate 11, and a temperature variation amount H1 up to the time t1 from when the wafer W is placed on the hot plate 11 and the heating of the wafer W is begun is, for example, 60° C. or less. Further, since the substrate processing system 1 is placed in the clean room as mentioned above, the temperature of the wafer W at the beginning of the heating is, for example, a set temperature of the clean room. Then, after the time t1, the purge gas is supplied into the processing vessel 12, and the top plate 14 is raised to the upper position. Then, at a time t2, the pins are raised to separate the wafer W from the hot plate 11, so the heating of the wafer W is stopped. Since the hydrophobization time is short, this time t2 is also a time before the wafer W reaches the set temperature B, the same as the time t1.

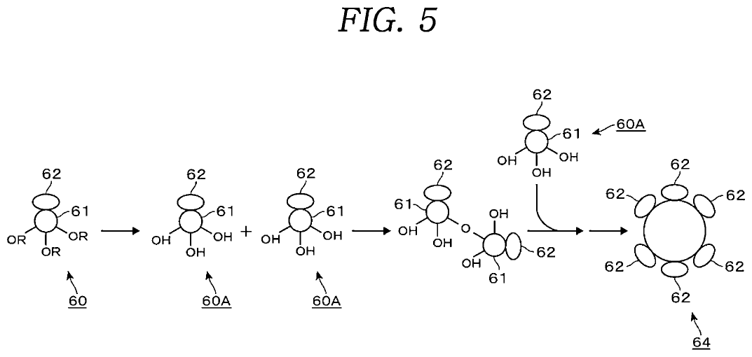

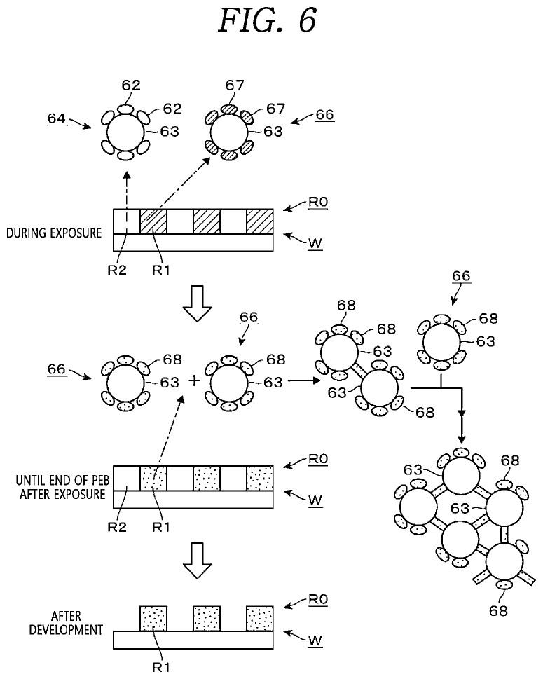

The reason why the hydrophobization on the surface of the wafer W on which the resist film is formed is limited as described above is to shorten a processing time for PEB and reduce a required exposure dose while improving the shape of the resist pattern. This will be explained later, and the processing of the wafer W after it is separated from the hot plate 11 will be explained. Hereinafter, reference will also be appropriately made to FIG. 5 and FIG. 6, which are schematic diagrams showing changes in resist. The wafer W is carried out of the processing vessel 12 by the transfer device 44. Then, the wafer W is transferred to the temperature regulating module SCPL to be adjusted to a predetermined temperature, and is then transferred to the holder of the coating module 10B by the transfer device 44, and the resist liquid is supplied from a non-illustrated reservoir to the nozzle.

When stored in this reservoir, a compound 60 constituting the resist has a structure including a nucleus 61 containing a metal, and OR groups (R portions are, for example, alkyl groups) and an organic ligand 62 bonded to the nucleus 61, as shown on the left side of FIG. 5. The resist liquid is supplied from the nozzle to the wafer W to form a resist film R0. Since this resist film R0 is formed on the surface of the wafer W whose moisture content has been reduced as a result of adjusting the moisture adhesion as described above, the amount of water introduced and mixed into the resist film R0 from the surface is suppressed. For this reason, the amount of moisture contained in the resist film R0 is suppressed.

Furthermore, when supplied to the wafer W to form the film in this way, the compound 60 comes into contact with a small amount of moisture in the atmosphere, so that the OR groups in the compound 60 are hydrolyzed into hydroxyl groups. The compound 60 changed to have the hydroxyl groups in this way is illustrated as a compound 60A in FIG. 5. The wafer W having the resist film R0 formed thereon in this way is transferred to the heat treatment module 10C, and the heating process (PAB) is performed. The compound 60A undergoes dehydration condensation until the PAB is completed, and becomes a cluster compound 64 having a nucleus 63 made of a metal oxide and a multiple number of ligands 62 located around the nucleus 63.

The wafer W after being subjected to the PAB is transferred by the transfer device 44 to the transition module TRS of the tower T2, and transferred to the transition module of the tower T3 by the transfer device 44 of the processing station S2 on the interface station S3 side.

The wafer W transferred to the transition module of the tower T3 is then transferred to the exposure device by the transfer devices 53 and 54 to be exposed into a predetermined pattern. By this exposure, in an exposure region R1 of the resist film R0, the ligands 62 in the cluster compound 64 are separated from the nucleus 63, and hydrogen are bonded to the nucleus 63 instead. At the top of FIG. 6, for the convenience' sake, the cluster compound changed in this way is indicated by a reference numeral 66, and the hydrogens in the cluster compound 66 are indicated by a reference numeral 67. Further, a non-exposure region R2 is still composed of the cluster compound 64.

The exposed wafer W is transferred to the transition module TRS of the tower T3 by the transfer devices 53 and 54. Thereafter, it is transferred to the heat treatment module 10C by the transfer device 44 to be subjected to the PEB. By reacting with moisture in the atmosphere until the PEB is completed, the hydrogens 67 in the cluster compound 66 are replaced with hydroxyl groups 68, and a cross-linking reaction due to the dehydration condensation between the cluster compounds 66 including these hydroxyl groups 68 proceeds. These series of reactions are schematically illustrated at the end of a dashed-line arrow in the middle of FIG. 6. These series of reactions cause the cluster compound 66 to be polymerized, thereby making the exposure region R1 insoluble in a developing liquid.

The wafer W after being subjected to the PEB in which the above-described reaction has occurred is then transferred to the developing module 10D by the transfer device 44 to be developed. As a result of supplying the developing liquid, the non-exposure region R2 that is not insolubilized is dissolved and removed, and the resist pattern is formed on the resist film R0 as shown at the bottom of FIG. 6. The wafer W upon the completion of the development is transferred to one of the heat treatment modules 10C by the transfer device 44 to be subjected to the HB. Afterwards, the wafer W is transferred to the transition module of the tower T1 by the transfer device 44, and is then transferred to the cassette C on the preset cassette placement table 41 by either one of the wafer transfer devices 42 and 43 of the cassette station S1. In this way, the series of processes of the photolithography are completed.

In order to explain the effect of the hydrophobization in this photolithography, a reaction regarded to take place when the respective processes of the photolithography are performed without performing the hydrophobization will be explained below. Since the hydrophobization is not performed, the resist film R0 is formed in the state that a relatively large amount of water is present on the surface of the wafer W. For this reason, the relatively large amount of water is introduced or mixed into the resist film R0 from the surface of the wafer W. As the amount of water contained in the resist film R0 becomes relatively large, this water causes the separation of some of the ligands 62 from the nucleus 61 or 63 as well as the hydrolysis of the OR groups as described in FIG. 5, so that some of the cluster compounds 64 are put into a state in which some of the ligands 62 that should be included therein are separated.

The cluster compounds 64 from which the ligands 62 are separated in this way are bonded to each other by using the sites from which the ligands 62 are released, thus forming a composite body instead of the polymers described in FIG. 6 before the exposure of the resist film R0 is performed. When this composite body is formed by the cluster compounds 64 from which only some of the ligands 62 are separated, the ligands 62 remaining in the cluster compounds 64, which are atom groups having a relatively large volume, interfere with each other, thus suppressing the nuclei 63 containing the metal from being densely arranged. Therefore, the composite body are less insoluble in the developing liquid than the polymer obtained when the reaction proceeds normally up to the PEB as described in FIG. 6.

For this reason, when a relatively large number of such a composite body is formed before the exposure process, it is needed to ensure the insolubility of the exposure region R1 in the development by allowing the corresponding reaction to proceed further with respect to the cluster compound 64 remaining in the resist film R0 so that the reaction described in FIG. 6 can occur. Specifically, it is necessary to make the exposure region R1 insoluble in the developing liquid by increasing the exposure dose to separate the ligands 62 from a larger number of cluster compounds 64, or by increasing the processing time for the PEB to allow the cross-linking reaction to proceed further.

Meanwhile, in the case where the ligands 62 do not separate from the cluster compound 64 before the exposure but separate during the exposure as shown in FIG. 6, the coordination of the nuclei 63 is not impeded by the ligands 62 when the nuclei 63 are bound, so that the nuclei 63 can be arranged in a dense manner. Therefore, by performing the above-described hydrophobization, it is possible to suppress the unnecessary separation of the ligands 62 before the exposure, and, therefore, when making the exposure region R1 insoluble, the exposure dose in the exposure device can be set to be relatively small (that is, the reaction sensitivity of the resist film R0 to the exposure can be increased), or the time required for the PEB can be shortened. These effects are observed from the evaluation tests to be described later.

Further, as will be described later in the evaluation tests, it is observed that if the hydrophobization is performed excessively, the non-exposure region R2 becomes insolubilized in the developing liquid (that is, the contrast of the pattern would deteriorate). This is deemed to be because the sensitivity to the exposure becomes too high due to the hydrophobization. In other words, it is assumed that the resist film R0 is put in a state where it is insolubilized even by a very small amount of light. Therefore, as explained in FIG. 3 and FIG. 4, by performing the limited hydrophobization on the wafer W, the exposure region R1 can be securely made insoluble in the developing liquid while maintaining the non-exposure region R2 soluble, thus achieving an effect of obtaining a good pattern shape of the resist film R0.

In addition, the substrate processing system 1 in the present disclosure is not limited to the configuration and operation described above. For example, the wafer W after being subjected to the PAB may be transferred to the peripheral exposure device by the transfer device 44 when necessary, and the exposure of the peripheral portion of the wafer W may be performed. Further, after the PAB, the wafer W may be cleaned in the cleaning device before the exposure process. Also, although the above exemplary embodiment has been described for the example where the wafer W is transferred between the interface station S3 and the exposure device, the exposure device may not be directly connected. In such a case, for example, the wafer W is transferred from the cassette station S1 to the processing station S2, and after a required process is performed, the wafer W is transferred back to the cassette station S1 to be taken out to the outside. That is, instead of carrying out the above-described series of processes of the photolithography on the wafer W after the wafer W is taken out of the cassette C until it is carried back into the cassette C, the cassette C may be transferred to multiple devices in sequence, and the wafers W may be processed in the respective devices, whereby the series of processes of the photolithography may be implemented.

In addition, the formation of the underlayer film may also be performed in the substrate processing system 1. In such a case, after coating a chemical liquid in the coating module 10B different from the coating module 10B for forming the resist film, the wafer W may be heated in the heat treatment module 10C different from the heat treatment module 10C for heating the resist film, and then subjected to the processes subsequent to the hydrophobization process described above. Further, among the processing devices mentioned above, one that is not necessary may not be provided, or a processing in that device may not be performed. In addition, the above-described locations of the various modules are not essential requirements, and they may be arranged at different positions appropriately. In such a case, the wafer W is appropriately transferred from one module to another in the order of processing as described above by using the transfer devices 42, 44, 53, 54, the towers T1 to T3, and so forth.

### <Decompressing Module>

In the above, the hydrophobizing module 10A has been described as an example of the substrate processing apparatus. However, an auxiliary process performed by an auxiliary processing module is not limited to the hydrophobization and may be another auxiliary process configured to reduce the amount of moisture adhesion to the surface of the wafer W. A decompressing module 10E, which is configured to perform decompression as another auxiliary process, will be explained below.

For example, the decompressing module 10E is disposed at the above-described position where the hydrophobizing module 10A is provided, in place of the hydrophobizing module 10A. Although the decompressing module 10E is equipped with the processing vessel 12, the same as the hydrophobizing module 10A, the top plate 14 is not provided with the suction port 18A, and by bringing the vessel body 13 and the top plate 14 into firm contact with each other in the state the top plate 14 is placed at the lower position, a sealed processing space is formed within the processing vessel 12. Then, the exhaust port 14C is opened at any position in a wall of the processing vessel 12 forming the processing space, and the processing space is evacuated by the exhaust mechanism 17 to become a decompressed space. The exhaust mechanism 17 and the exhaust port 14C correspond to a decompressor.

Further, instead of the hot plate 11, the vessel body 13 is provided with, for example, a stage configured to place the wafer W thereon without having a function of adjusting the temperature of the wafer W. The gas supply mechanism 16 of the decompressing module 10E is configured to supply a low-humidity gas, allowing a supply of the low-humidity gas from the discharge opening 14B and an exhaust of the gas from the exhaust port 14C. Here, the low-humidity gas refers to a gas having humidity lower than that of the clean room in which the substrate processing system 1 is disposed, and is, for example, an inert gas such as a nitrogen gas or an argon gas, or dry air.

With the wafer W placed on the stage, the sealed processing space is formed, and as the pressure of the sealed space within the processing vessel 12 is reduced from a normal pressure by the evacuation of the processing vessel 12, the processing space is turned into the decompressed space, and the moisture adhering to the surface of the wafer W is vaporized to be removed from the wafer W. Subsequently, as the low-humidity gas is supplied from the discharge opening 14B, the pressure in the sealed space returns to the normal pressure, while suppressing re-adhesion of the moisture. Then, the processing vessel 12 is opened, and the wafer W is taken out. In this way, the amount of water adhesion to the wafer W during the resist film formation is reduced. Here, the adjusting the moisture adhesion to the surface of the wafer W includes not only reducing the adhesive property of water through the hydrophobization but also directly reducing the amount of the water adhesion in this manner.

However, since the suppression of the amount of the water adhesion is included, the moisture may be removed by only performing the heating of the wafer W in the above-described hydrophobizing module 10A, for example, without supplying the hydrophobizing gas. In such a case, however, when cooling the wafer W in the coating module 10B and returning the temperature of the wafer W back to the room temperature, there is a risk that moisture around the wafer W may re-attach to the wafer W. Therefore, when performing the heating of the wafer W, there may be adopted a configuration in which a low-humidity gas can be supplied into the processing vessel 12, the same as in the decompressing module 10E, for example, and the wafer W may be cooled by this low-humidity gas.

In addition, this heating is assumed to be the heating performed separately from the PAB that is performed to form the underlayer film of the resist film. That is, the underlayer film formed under the resist film, such as an anti-reflection film, is formed by coating a chemical liquid, and then PAB for the underlayer film is performed by heating and vaporizing a solvent in the underlayer film. The heating described here is a different process from the PAB. In other words, the heating is assumed to be heating performed after the wafer W is received by the transfer device after the PAB for the underlayer film is performed.

Further, when moisture is removed by the decompression or the heating process, the re-adhesion of moisture to the surface of the wafer W can be suppressed by, for example, lowering the humidity of the space in which the wafer W is transferred for the processes ranging from this corresponding process to the coating of the resist film. As a specific example, as for the transfer region of the wafer W by the transfer device and the module that form the space together, the low-humidity gas described above is supplied to the transfer region of the wafer W. Also, even when performing the hydrophobization, the space in which the wafer W is transferred may be lowered in humidity in this way to more reliably suppress the moisture adhering to the wafer W from being supplied to the resist film. In addition, when the moisture is removed from the surface of the wafer W by the decompression or heating process as the adjustment of the moisture adhesion of, there is no limitation on the amount of moisture remaining on the surface of the wafer W after the process. That is, the process may be performed so that some of the moisture adhering to the wafer W remains, or the process may be performed so that all or substantially all of the moisture is removed from the surface of the wafer W.

However, when transferring the wafer W after being processed as described above in the decompressing module 10E (this wafer W will be referred to as a wafer W2) to the coating module 10B, if another wafer (referred to as a wafer W1) is being processed in the coating module 10B as a transfer destination of the wafer W2, a transfer device, for example, stands by in front of the coating module 10B while holding the wafer W2 until the wafer W1 can be carried out from the coating module 10B, which results in a delay of the carry-in of the wafer W2 into the coating module 10B. If the carry-in delay times varies among the wafers W in the same lot, the amount of moisture in the atmosphere that adheres to the wafers W varies, which may result in non-uniform pattern shapes.

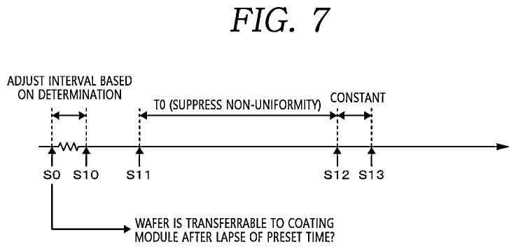

Hereinafter, reference will be made to a time chart of FIG. 7 as well. In order to suppress the aforementioned non-uniformity of the pattern shape, a variation in time T0 ranging from a time S11 upon the completion of the decompression process by the decompressing module 10E to a time S12 when the wafer W is carried into the coating module 10B is suppressed between wafers W of the same lot. Further, since a time length from when the wafer W is carried into the coating module 10B until the process in the coating module 10B is started is constant, uniforming the time T0 from the time S11 to the time S12 also implies uniforming a time from the time S11 to a time S13 when the resist film formation is begun. The time S11 upon the completion of the decompression process by the decompressing module 10E refers to a timing when the processing vessel 12 is opened due to the ascent of the top plate 14 (that is, a timing when the wafer W is exposed to the outside of the processing vessel 12). Further, suppressing the variation in the time T0 from the time S11 to the time S12 between the wafers W of the same lot means that the variation in the time T0 is, for example, 10 seconds or less, and it is desirable that the variation in the time T0 is 0 second. The variation in the time T0 is suppressed by adjusting a process start time S10 in the decompressing module 10E.

Once the wafer W is placed on the stage of the decompressing module 10E, the control device 100 calculates a time S14 upon the lapse of a preset processing time in the decompressing module 10E plus a predetermined time required for the transfer of the wafer W from the decompressing module 10E to the coating module 10B from a time S0 when the wafer W is placed on the stage. Then, at this time S14, it is determined whether or not a previously transferred wafer W is present in the coating module 10B. If it is determined that the wafer W is not present, the decompression process is promptly started. If, however, it is determined that the wafer W is present, a required time TT from the time S14 until the wafer W is carried out from the coating module 10B is calculated. When it is determined that the wafer W is present, the decompression process is begun after a preset time corresponding to the time TT elapses from the time S0. The time corresponding to the time TT may be the time TT itself.

In this way, for each of the wafers W in the lot, the process start time S10 in the decompressing module 10E is determined according to a carry-in timing at which each wafer W is carried into the coating module 10B, and the variation in the time T0 is suppressed as described above. Since a timing of a start of a process in the coating module 10B is based on the carry-in timing, it can also be said that the determination of the decompression process start time S10 is made according to the timing of the start of the process in the coating module 10B. By determining the process start time S10 in this way, the delay in the transfer of the wafer W to the coating module 10B is eliminated, so that the variation in the time T0 is suppressed. Further, various calculations, determinations, and decisions for determining the above-described timing for the start of the decompression process are performed by the control device 100.

The process start time S10 of the decompressing module 10E is a timing when the inside of the processing vessel 12 is turned into the sealed space and the decompression is started. This process starting timing can also be adjusted in the same way when the hydrophobizing module 10A is provided instead of the decompressing module 10E. The process start time S10 in the hydrophobizing module 10A is a time when the valve V1 is opened to supply the hydrophobizing gas to the wafer W, and the process completion time S11 is a time when the valve V1 is closed. Therefore, the times t0 and t1 shown in FIG. 4 correspond to the process start time S10 and the process completion time S11 of FIG. 7. However, since the hydrophobization is a process to suppress adhesion of water, a change in the pattern shape due to re-adhesion of moisture is less likely to occur in the hydrophobization process, as compared to the decompression process in the decompressing module 10E. Thus, the transfer control described in FIG. 7 is particularly useful when a process is performed in the decompressing module 10E.

As described above, before the wafer W is transferred to the coating module 10B, it is carried into the temperature regulating module SCPL where its temperature is adjusted. In the above-described transfer of the wafer W in FIG. 7, it is assumed that there is no delay in the transfer of the wafer W from the decompressing module 10E to the temperature regulating module SCPL by providing a multiple number of temperature regulating modules SCPL, for example.

Examples of the silane coupling agent contained in the gas supplied by the hydrophobizing module 10A may include, in addition to the HMDS, trimethylsilyldimethylamine (TMSDMA), trimethylsilyldiethylamine (TMSDEA), dimethyl(dimethylamino) silane (DMSDMA), 1,1,3,3-tetramethyldisilane (TMDS), polysilazane, and siloxane, and they may be used. Moreover, the silane coupling agent is not limited to being supplied to the wafer W in a gaseous state, but may be supplied to the wafer W in a liquid state. For example, the silane coupling agent may be applied by spin coating, the same as the resist. As stated above, however, if the hydrophobization proceeds excessively, a problem may occur in the pattern shape. To suppress the problem, the concentration of the silane coupling agent in the liquid is appropriately adjusted.

Although the formation of the resist film has been described as being implemented by the liquid processing, it is not limited to the liquid processing. For example, the resist film may be formed by supplying a film forming gas for forming the resist film instead of the hydrophobizing gas by using a module having the same configuration as the hydrophobizing module 10A. Besides, the processes, such as the development and the formation of the underlayer film, described as being performed by using a processing liquid may be implemented by supplying a processing gas instead of supplying the processing liquid, the same as in the case of forming the resist film.

In addition, regarding the location of the hydrophobizing module 10A and the coating module 10B, they may be disposed in the second block G2, which is described above as being a place where the heat treatment module 10C is disposed, besides in the first block G1. Further, the hydrophobizing module 10A may be disposed in, for example, the tower T1 of the cassette station S1, and there may be adopted a configuration in which the wafer W after being subjected to the hydrophobization process in the cassette station S1 is transferred to the processing station S2 to be subjected to the formation of the resist film in the processing station S2. Further, the respective modules including the hydrophobizing module 10A and the coating module 10B may be disposed at places accessibly by the respective transfer devices, other than the example places described above. The number and the layout of the transfer devices are not limited to the example of the present disclosure, and may be selected appropriately.

The hydrophobizing module 10A will be further explained. Although the wafer W is heated by being placed on the hot plate 11 in the above-described example, a heater for heating the wafer W is not limited to the hot plate 11. For example, the heater may be an LED, and the wafer W may be heated by light radiation from the LED. Even in this case, the supply of the hydrophobization gas may be stopped before the wafer W reaches the set temperature B at which the temperature rise saturates as shown in FIG. 4, for example.

Since the hydrophobization of the surface of the wafer W only needs to be done sparsely, the hydrophobization process is stopped (that is, a temperature variation of the wafer W is suppressed) before the wafer W reaches the set temperature B in FIG. 4 in order to enable the wafer W to be quickly carried out from the hydrophobizing module 10A to thereby increase a throughput of the substrate processing system 1. However, this does not need to be done in heating the wafer W with the hot plate 11 or the LED, and the hydrophobization process may be performed by supplying the hydrophobization gas to the wafer W after the temperature of the wafer W reaches the set temperature B. The substrate processed by the technique of the present disclosure is not limited to the wafer W, and may be any of various other types of substrates such as a substrate for manufacturing a flat panel display.

Now, evaluation tests performed in relation to the technique of the present disclosure will be explained.

### [Evaluation Test 1]

In Evaluation Test 1, the hydrophobization, the formation of the resist film R0, the exposure by EUV, the PEB, the development, and the HB are sequentially performed on a plurality of wafers W as described in the above exemplary embodiment, and a residual film amount (film thickness of remaining resist film) in the exposure region R1 is measured. In the above-described series of processes, the exposure dose is changed between the wafers W, and a relationship between the exposure amount and the remaining film amount is investigated from measurement results. Also, the hydrophobization time (time during which the hydrophobizing gas is supplied) is set to 10 seconds, 30 seconds, or 60 seconds. Tests conducted by setting the hydrophobization time to 10 seconds, 30 seconds, and 60 seconds are referred to as Evaluation Tests 1-1, 1-2, and 1-3, respectively. Additionally, an exposure device equipped with a KrF (krypton fluoride) light source is used for the exposure, and the PEB is performed for 60 seconds.

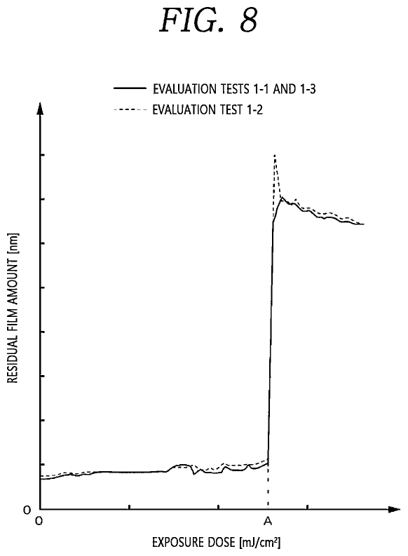

FIG. 8 is a graph showing a summary of the results of Evaluation Test 1. A horizontal axis and a vertical axis represent an exposure dose and a residual film amount, respectively, and graduations are given at a regular interval on each of the horizontal and vertical axes. As shown in this graph, in all of Evaluation Tests 1-1 to 1-3, the residual film amount changes largely at an exposure dose value A as a boundary, and three is no significant difference in the residual film amount when the exposure dose is the same between Evaluation Tests 1-1 to 1-3. Therefore, it is confirmed that the difference in the hydrophobization time between Evaluation Tests 1-1 to 1-3 does not affect the insolubilization reaction of the resist film in the exposed region to the developing liquid.

As described above, there is no significant difference for the exposed region R1 between Evaluation Tests 1-1 to 1-3. However, in Evaluation Tests 1-2 and 1-3, it is found out that so-called bridge defects have occurred, so a protrusion is formed in the non-exposure region R2 as well so as to be connected to a protrusion of the pattern formed in the exposure region R1. Meanwhile, no bridge defect is observed in Evaluation Test 1-1. Therefore, it is confirmed from this Evaluation Test 1 that if the hydrophobization is excessively performed (that is, if the contact angle of the resist film formation surface with the pure water becomes too high), an unnecessary reaction may progress in the non-exposure region R2, raising a risk that a normal pattern may not be formed.

For convenience' sake, an exposure dose that is a boundary value at which the residual film amount changes greatly between ranges above and below that value, such as the value A of the above-described graph, will be referred to as an insolubilizing exposure dose hereinafter. As will be shown later as a result of Evaluation Test 2, a graph showing a relationship between the exposure dose and the residual film amount, such as the one shown in FIG. 8, is obtained for each of a case where the above-described series of processes from the hydrophobization to the HB are performed and a case where, among the series of processes, the hydrophobization is not performed. The insolubilizing exposure dose of this graph is found to be smaller when the hydrophobization is performed than when the hydrophobization is not performed. In other words, it is proved that by performing the hydrophobization, the insolubilization of the resist film with respect to the developing liquid has occurred with a relatively small exposure dose. As can be seen from such a difference depending on whether or not the hydrophobization is performed and the result of Evaluation Test 1, it is desirable to set the hydrophobization time to a relatively short time of, e.g., 10 seconds or less. Also, as stated in the exemplary embodiment, it is assumed that performing the hydrophobization sparsely is effective.

### [Evaluation Test 2]

In this evaluation test, an effect of presence or absence of hydrophobization on exposure sensitivity of the resist film and an effect of a PEB time on the exposure sensitivity are investigated. In Evaluation Test 2-1, a series of processes are performed on the wafer W in the same manner as in Evaluation Test 1, with the hydrophobization time being 10 seconds and the PEB time being 60 seconds. In Evaluation tests 2-2, 2-3, and 2-4, the PEB time is set to 120 seconds, 300 seconds, and 60 seconds, respectively, and the wafer W is processed in the same manner as in Evaluation Test 2-1, except that the hydrophobization is not performed. Then, a graph showing a relationship between an exposure dose and a residual film amount is obtained from each wafer W after being processed, the same as in Evaluation Test 1.

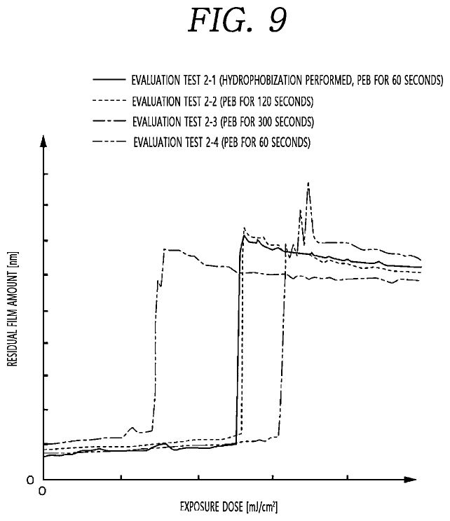

FIG. 9 shows this graph. As can be seen from this graph, the resist film of the wafer W in Evaluation Test 2-1 is insolubilized with an exposure dose of about 20% less than that of the resist film of the wafer W in Evaluation Test 2-4, which is performed under the same conditions except that no hydrophobization is performed. This shows that the exposure sensitivity of the resist film is improved by the hydrophobization process of the present disclosure. Furthermore, it is also found out from the graph that the residual film amount at an exposure dose greater than the insolubilization exposure dose in Evaluation Test 2-1 is smaller than the residual film amount at an exposure dose greater than the insolubilization exposure dose in Evaluation Test 2-4. This is assumed to be because many cross-linking reactions occur due to the hydrophobization, causing the resist film to shrink.

As for which insolubilizing exposure doses are larger, there is a relationship of Evaluation Tests 2-4>2-2>2-3. In other words, the longer the PEB time, the smaller the insolubilizing exposure dose. Also, as for which residual film amounts at exposure doses equal to or greater than the insolubilizing exposure dose, there is a relationship of Evaluation Tests 2-3<2-2<2-4. This suggests that the cross-linking reaction progresses as the PEB time increases. In Evaluation Test 2-2, the PEB is performed for 60 seconds longer instead of performing the hydrophobization, as compared to Evaluation Test 2-1. Between these Evaluation Tests 2-1 and 2-2, however, the insolubilizing exposure dose and the residual film amount at exposure doses equal to or greater than the insolubilizing exposure dose are found to be the same. In other words, it is confirmed that performing the hydrophobization has the same effect as performing the PEB of 60 seconds. Therefore, it is proved that the PEB time can be shortened by performing the hydrophobization. As stated in Evaluation Test 1, the time required for the hydrophobization is relatively short. Thus, it is provided from the results of Evaluation Tests 1 and 2 that by performing the hydrophobization, the time required for the PEB can be made relatively short, so that the time required to complete the HB on the wafer W can be shortened, and the throughput can be improved.

It should be noted that the above-described exemplary embodiment is illustrative in all aspects and is not anyway limiting. The above-described exemplary embodiment may be omitted, replaced and modified in various ways without departing from the scope and the spirit of claims.

According to the exemplary embodiment, it is possible to satisfactorily form the pattern on the metal-containing resist film.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing method of patterning a resist film formed on a substrate by exposing and developing the resist film, the substrate processing method comprising:
performing, before forming the resist film containing a metal on the substrate, an auxiliary process of adjusting moisture adhesion to a formation surface of the substrate on which the resist film is to be formed.

2. The substrate processing method of claim 1,
wherein the auxiliary process is hydrophobization of the formation surface.

3. The substrate processing method of claim 2,
wherein in the auxiliary process, a contact angle of pure water on the formation surface is set to be equal or higher than 30 degrees and less than 65 degrees.

4. The substrate processing method of claim 2,
wherein the auxiliary process is supplying a processing gas used in the hydrophobization to the formation surface and heating the substrate by a heater, and
a temperature variation amount of the substrate from a start of the hydrophobization to an end of the hydrophobization is 60° C. or less.

5. The substrate processing method of claim 1,
wherein the auxiliary process is removing moisture from the formation surface by decompressing a processing vessel in which the substrate is placed into a decompressed space.

6. The substrate processing method of claim 1, further comprising:
adjusting a timing of starting the auxiliary process based on a timing of starting formation of the resist film.

7. The substrate processing method of claim 6, further comprising:
determining, in performing the auxiliary process and the formation of the resist film on multiple substrates in sequence, the timing of starting the auxiliary process on each of the multiple substrates such that a difference in time from a timing of ending the auxiliary process to the timing of starting the formation of the resist film is suppressed between the multiple substrates.

8. A substrate processing apparatus configured to process a substrate, in which a resist film is formed and the resist film is patterned by being exposed and developed,
wherein before forming the resist film containing a metal on the substrate, an auxiliary process of adjusting moisture adhesion to a formation surface of the substrate on which the resist film is to be formed is performed.

9. The substrate processing apparatus of claim 8,
wherein the auxiliary process is hydrophobization of the formation surface.

10. The substrate processing apparatus of claim 8, comprising:
a processing vessel in which the substrate is placed; and
a decompressor configured to decompress the processing vessel into a decompressed space to remove moisture from the formation surface.

11. A computer-readable recording medium having stored thereon computer-executable instructions that, in response to execution, cause a substrate processing apparatus to perform a substrate processing method as claimed in claim 1.
